(19) United States
(12) Patent Application Publication
(10) Pub. No.: US 2024/0353944 A1
(43) Pub. Date: Oct. 24, 2024

(54) DISPLAY PANEL AND DISPLAY APPARATUS

(71) Applicants: Wuhan Tianma Microelectronics Co., Ltd., Wuhan (CN); Wuhan Tianma Microelectronics Co., Ltd. Shanghai Branch, Pudong New District, Shanghai (CN)

(72) Inventors: Siyu CHEN, Wuhan (CN); Wenxin JIANG, Wuhan (CN); Xuhui PENG, Wuhan (CN); BONGGEUM LEE, Wuhan (CN); Chong QIAN, Wuhan (CN); Qing HE, Wuhan (CN)

(21) Appl. No.: 18/762,704

(22) Filed: Jul. 3, 2024

(30) Foreign Application Priority Data
Dec. 21, 2023 (CN) 202311783756.3

(51) Int. Cl. G06F 3/041; G06F 3/044; H10K 59/122; H10K 59/131; H10K 59/40

(52) U.S. Cl. CPC G06F 3/0412; G06F 3/04164; H10K 59/122; H10K 59/1315; H10K 59/40; G06F 3/0443

(57) ABSTRACT

Provided are a display panel and a display apparatus. The display panel includes a first electrode layer including display electrodes and touch electrodes, light-emitting elements, touch signal lines electrically connected to the touch electrodes, and first power supply voltage signal lines electrically connected to the display electrodes. The display electrodes are arranged in a same layer as the touch electrodes and insulated from the touch electrodes. The first power supply voltage signal lines and the touch signal lines are formed in a same layer. Each light-emitting element includes a driving electrode, a light-emitting material and a display electrode of the display electrodes. The driving electrode, the light-emitting material and the display electrode are stacked on one another. The display electrode is located on a side of the light-emitting material facing a light-exiting surface of the display panel.

### CROSS-REFERENCE TO RELATED APPLICATIONS

The present disclosure claims priority to Chinese Patent Application No. 202311783756.3, filed on Dec. 21, 2023, the content of which is incorporated herein by reference in its entirety.

### TECHNICAL FIELD

The present disclosure relates to the display field, and in particular, to a display panel and a display apparatus.

### BACKGROUND

In the field of touch display technology, in order to further reduce a thickness of a display panel, touch units are usually placed below an encapsulation layer, that is, an in-cell touch technology is employed to realize the touch function of the display panel.

At present, in order to realize the in-cell touch technology, a cathode layer of the display panel is usually patterned, some of the cathodes are used as display electrodes, and some of the cathodes are used as touch electrodes. However, in order to ensure the normal operation of the display electrodes and the touch electrodes, the manufacturing process of the in-cell touch technology is complex and difficult. Therefore, a solution is urgently needed to solve the above problem.

### SUMMARY

In a first aspect of the present disclosure, a display panel is provided. The display panel includes a first electrode layer including a plurality of display electrodes and a plurality of touch electrodes, a plurality of light-emitting elements, a plurality of touch signal lines electrically connected to the plurality of touch electrodes, and a plurality of first power supply voltage signal lines electrically connected to the plurality of display electrodes. The plurality of display electrodes are arranged in a same layer as the plurality of touch electrodes and insulated from the plurality of touch electrodes. Each light-emitting element includes a driving electrode, a light-emitting material and a display electrode of the plurality of display electrodes. The driving electrode, the light-emitting material and the display electrode are stacked on one another, and the display electrode is located on a side of the light-emitting material facing a light-exiting surface of the display panel. The plurality of first power supply voltage signal lines and the plurality of touch signal lines are formed in a same layer.

In a second aspect of the present disclosure, a display apparatus is provided. The display apparatus includes a display panel. The display panel includes a first electrode layer including a plurality of display electrodes and a plurality of touch electrodes, a plurality of light-emitting elements, a plurality of touch signal lines electrically connected to the plurality of touch electrodes, and a plurality of first power supply voltage signal lines electrically connected to the plurality of display electrodes. The plurality of display electrodes are arranged in a same layer as the plurality of touch electrodes and insulated from the plurality of touch electrodes. Each light-emitting element includes a driving electrode, a light-emitting material and a display electrode of the plurality of display electrodes. The driving electrode, the light-emitting material and the display electrode are stacked on one another, and the display electrode is located on a side of the light-emitting material facing a light-exiting surface of the display panel. The plurality of first power supply voltage signal lines and the plurality of touch signal lines are formed in a same layer.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may also be obtained based on these drawings.

FIG. 1 is a plan view of a display panel according to some embodiments of the present disclosure;

FIG. 2 is an enlarged view of a region Q in FIG. 1 according to some embodiments of the present disclosure;

FIG. 3 is a schematic structural diagram of a display panel according to some embodiments of the present disclosure;

FIG. 4 is a plan view of a touch signal line and a first power supply voltage signal line according to some embodiments of the present disclosure;

FIG. 5 is a schematic structural diagram of another display panel according to some embodiments of the present disclosure;

FIG. 6 is a plan view of another touch signal line and another first power supply voltage signal line according to some embodiments of the present disclosure;

FIG. 7 is a schematic structural diagram of another display panel according to some embodiments of the present disclosure;

FIG. 8 is a schematic structural diagram of another display panel according to some embodiments of the present disclosure;

FIG. 9 is a schematic diagram of a display electrode according to some embodiments of the present disclosure;

FIG. 10 is a schematic diagram of another display electrode according to some embodiments of the present disclosure;

FIG. 11 is a schematic diagram of another display electrode according to some embodiments of the present disclosure;

FIG. 12 is another enlarged view of a region Q shown in FIG. 1 according to some embodiments of the present disclosure;

FIG. 13 is an enlarged view of a display electrode shown in FIG. 12 according to some embodiments of the present disclosure;

FIG. 14 is a cross-sectional view taken along line MN′ shown in FIG. 12 according to some embodiments of the present disclosure;

FIG. 15 is a schematic diagram of another display electrode according to some embodiments of the present disclosure;

FIG. 16 is a schematic diagram of another display electrode according to some embodiments of the present disclosure;

FIG. 17 is a plan view of another display panel according to some embodiments of the present disclosure;

FIG. 18 is a plan view of another display panel according to some embodiments of the present disclosure;

FIG. 19 is a schematic structural diagram of another display panel according to some embodiments of the present disclosure;

FIG. 20 is a plan view of another display panel according to some embodiments of the present disclosure;

FIG. 21 is a schematic structural diagram of another display panel according to some embodiments of the present disclosure;

FIG. 22 is another enlarged view of a region Q in FIG. 1 according to some embodiments of the present disclosure;

FIG. 23 is a schematic diagram showing connections of touch electrodes according to some embodiments of the present disclosure; and

FIG. 24 is a schematic diagram of a display apparatus according to some embodiments of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

In this specification, it should be understood that the terms “basically”, “approximately”, “roughly”, “about”, “generally” and “substantially” described in the claims and embodiments of this disclosure refer to a reasonable process operation range or tolerance range, which can be substantially agreed, rather than an exact value.

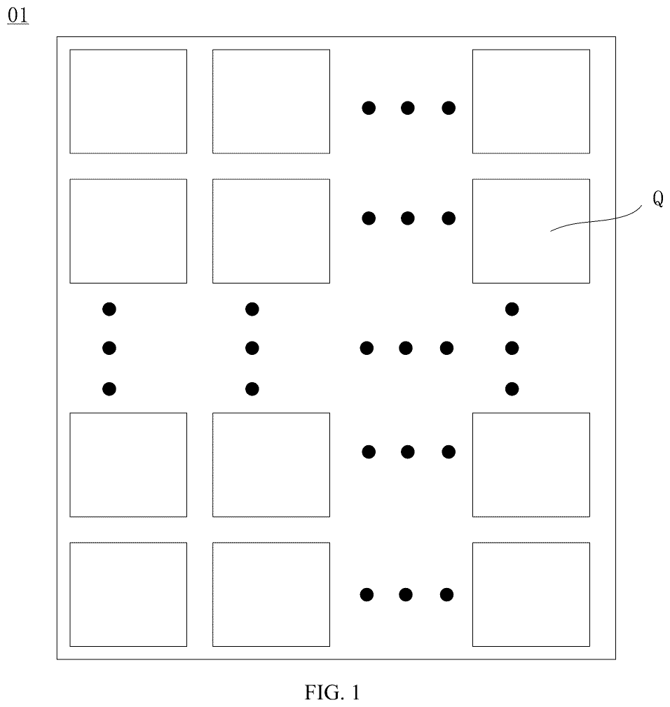

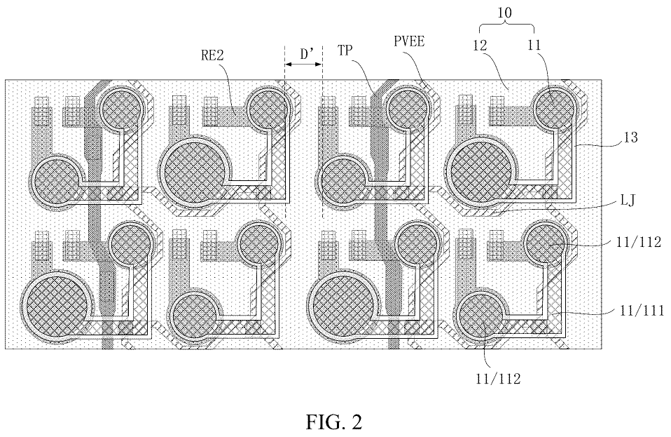

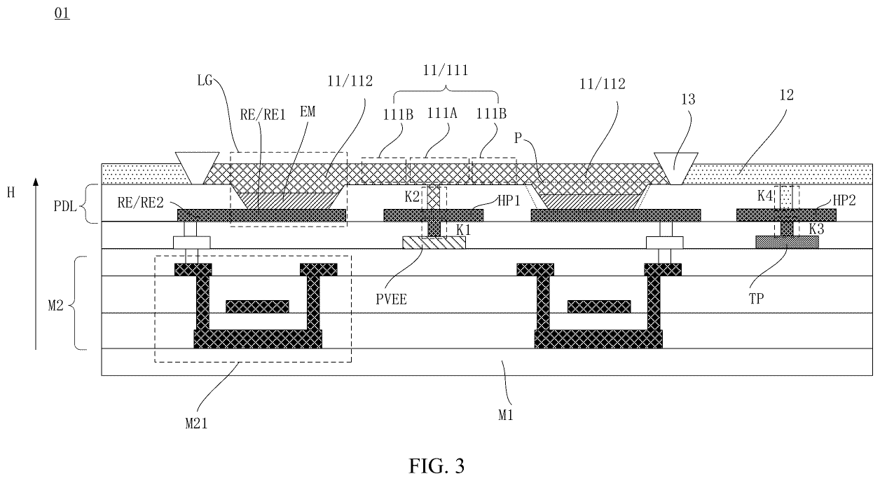

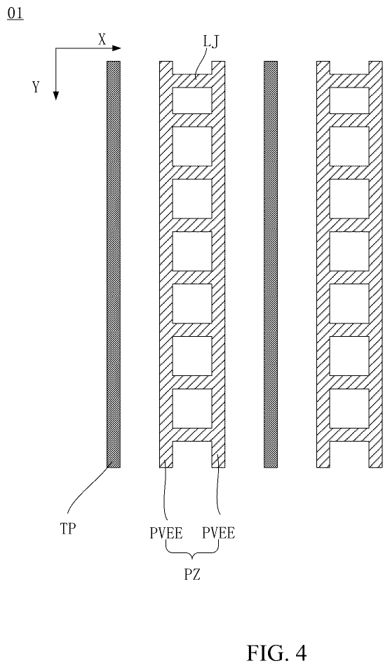

FIG. 1 is a plan view of a display panel according to some embodiments of the present disclosure. FIG. 2 is an enlarged view of a region Q in FIG. 1 according to some embodiments of the present disclosure. FIG. 3 is a schematic structural diagram of a display panel according to some embodiments of the present disclosure. FIG. 4 is a plan view of a touch signal line and a first power supply voltage signal line according to some embodiments of the present disclosure.

Embodiments of the present disclosure provide a display panel 01. As shown in FIG. 1 and FIG. 2, the display panel 01 includes a first electrode layer 10. The first electrode layer 10 includes a plurality of display electrodes 11 and a plurality of touch electrodes 12. The same one touch electrode 12 surrounds multiple display electrodes 11, and an entity part of the touch electrode 12 is located between two adjacent display electrodes 11. The display electrodes 11 are electrically insulated from the touch electrodes 12. Adjacent touch electrodes 12 are electrically insulated from each other.

In some embodiments of the present disclosure, as shown in FIG. 2, a blocking wall 13 may be arranged between a display electrode 11 and a touch electrode 12 adjacent to the display electrode 11. The display electrode 11 and the touch electrode 12 are spaced apart by the blocking wall 13. In some embodiments of the present disclosure, another blocking wall 13 may be arranged between adjacent touch electrodes 12 for separating the adjacent touch electrodes 12. The first electrode layer 10 may be formed integrally by an evaporation process. During the evaporation of the first electrode layer 10, the first electrode layer 10 breaks at the blocking wall 13, and thus the display electrode 11 and the touch electrode 12 are formed.

It should be noted that a region Q shown in FIG. 1 may be regarded as a touch electrode region, and one region Q includes one touch electrode 12. The blocking wall 13 is provided between two adjacent regions Q to ensure the electrical insulation between touch electrodes 12 in the two regions Q.

As shown in FIG. 3, the display panel 01 includes a plurality of light-emitting elements LG. Each light-emitting element LG includes a driving electrode RE, a light-emitting material EM, and a display electrode 11 that are stacked on one another. The display electrode 11 is located on a side of the light-emitting material EM adjacent to a light-exiting surface of the display panel 01. That is, the display electrode 11 may be the cathode of the light-emitting element LG, and the driving electrode RE may be the anode of the light-emitting element LG.

In some embodiments of the present disclosure, as shown in FIG. 3, the display panel 01 further includes a substrate M1 and a transistor array layer M2. The transistor array layer M2 is arranged between the substrate M1 and the light-emitting element LG. The transistor array layer M2 includes a pixel circuit M21. The pixel circuit M21 is electrically connected to the driving electrode RE of the light-emitting element LG and supplies a driving signal to the driving electrode RE.

As shown in FIG. 1 to FIG. 4, the display panel 01 further includes a plurality of touch signal lines TP and a plurality of first power supply voltage signal lines PVEE. The first power supply voltage signal line PVEE is electrically connected to the display electrode 11 and supplies a common voltage signal to the display electrode 11. The plurality of display electrodes 11 in the plurality of light-emitting elements LG receive the same common voltage signal.

In some embodiments of the present disclosure, as shown in FIG. 2 and FIG. 3, the first power supply voltage signal line PVEE is electrically connected to the display electrode 11 through a conductive via hole, and one first power supply voltage signal line PVEE may be electrically connected to multiple display electrodes 11.

The touch signal line TP is electrically connected to the touch electrode 12 and transmits a touch signal. Different touch electrodes 12 are electrically connected to different touch signal lines TP.

In some embodiments of the present disclosure, as shown in FIG. 2 and FIG. 3, the touch signal line TP may be electrically connected to the touch electrode 12 through a conductive via hole. In some embodiments of the present disclosure, the touch electrode 12 is a self-capacitance touch electrode.

The first power supply voltage signal line PVEE and the touch signal line TP are formed in a same layer. In other words, the first power supply voltage signal line PVEE and the touch signal line TP are formed simultaneously in the manufacturing process of the display panel 01.

In the existing display panel, the first power supply voltage signal line and the touch signal line are typically formed in different layers. Therefore, in the manufacturing process of the display panel, the manufacturing of the first power supply voltage signal line needs one mask, the manufacturing of the conductive via hole electrically connecting the first power supply voltage signal line and the display electrode needs one mask, the manufacturing of the touch signal line also needs one mask, and the manufacturing of the conductive via hole electrically connecting the touch signal line and the touch electrode needs one mask. That is, in order to supply signals to the display electrode and the touch electrode, four masks are added in the manufacturing process of the display panel, which increases the complex degree and difficulty of the manufacturing of the display panel.

In some embodiments of the present disclosure, the first power supply voltage signal line PVEE and the touch signal line TP are formed in a same layer, so the manufacturing of the first power supply voltage signal line PVEE and the manufacturing of the touch signal line TP may share the same mask. In addition, the display electrode 11 and the touch electrode 12 are formed in the same layer, so the manufacturing of the conductive via hole electrically connecting the first power supply voltage signal line PVEE and the display electrode 11 and the manufacturing of the conductive via hole electrically connecting the touch signal line TP and the touch electrode 12 may share the same mask. In this way, the number of masks required in the manufacturing process of the display panel 01 is reduced, and the difficulty and cost of manufacturing the display panel 01 are reduced.

As shown in FIG. 4, in some embodiments of the present disclosure, the plurality of touch signal lines TP are arranged along a first direction X, and each touch signal line TP extends along a second direction Y, the plurality of first power supply voltage signal lines PVEE are arranged along the first direction X, and each first power supply voltage signal line PVEE extends along the second direction Y. The first direction X intersects the second direction Y.

In some embodiments of the present disclosure, the first direction X is the row direction in the display panel 01, and the second direction Y is the column direction of the display panel 01.

At least some adjacent first power supply voltage signal lines PVEE are electrically connected by a plurality of connection lines LJ. The connection lines LJ are arranged along the second direction Y, and each connection line LJ extends along the first direction X. The connection line LJ extending along the first direction X is electrically insulated from the touch signal line TP.

In some embodiments of the present disclosure, at least some adjacent first power supply voltage signal lines PVEE are electrically connected by connection lines LJ, so at least some first power supply voltage signal lines PVEE are arranged in a mesh pattern. In this way, the voltage drop of a signal transmitted on the first power supply voltage signal line PVEE is reduced, the accuracy of the signal received by the display electrode 11 is improved, and the display effect of the display panel 01 is improved.

In addition, the mesh arrangement of at least some adjacent first power supply voltage signal lines PVEE prevents the integral of the first power supply voltage signal lines PVEE and the connection lines LJ from occupying a large area. In this way, the parasitic capacitance between the integral of the first power supply voltage signal lines PVEE and the connection lines LJ and a signal in another layer, and the stability of signals transmitted in various layers of the display panel 01 is improved.

In some embodiments of the present disclosure, at least two first power supply voltage signal lines PVEE adjacent in the first direction X form a first signal line group PZ. In the first direction X, the first signal line groups PZ are arranged alternately with the touch signal lines TP. In this way, the first power supply voltage signal lines PVEE in the display panel 01 are distributed evenly, improving the uniformity of the signals received by the display electrodes 11.

In addition, the display panel 01 includes N1 first power supply voltage signal lines PVEE and N2 touch signal lines TP, and N1 and N2 are positive integers greater than 1, and ¼≤N2/N1≤½. In this way, at least two first power supply voltage signal lines PVEE adjacent in the first direction X form the first signal line group PZ, and the first signal line groups PZ are arranged alternately with the touch signal lines TP.

In some embodiments of the present disclosure, as shown in FIG. 4, the first power supply voltage signal lines PVEE in the same first signal line group PZ are electrically connected by the connection lines LJ, and the connection lines LJ and the first power supply voltage signal lines PVEE are formed in the same layer.

In this embodiment, the first signal line group PZ between two adjacent touch signal lines TP may be arranged in a mesh shape, and the connection lines LJ electrically connecting the first power supply voltage signal lines PVEE in the same first signal line group PZ do not extend to the position of the touch signal lines TP. In this way, the touch signal lines TP do not connect the touch signal lines TP, the touch signal lines TP are electrically insulated from the touch signal lines TP, and thus, the first power supply voltage signal lines PVEE are electrically insulated from the touch signal lines TP.

The connection lines LJ and the first power supply voltage signal lines PVEE may be formed in the same layer, so an additional process of manufacturing the connection lines LJ is not required, and the manufacturing difficulty of the display panel 01 is not increased.

It should be noted that, in some embodiments of the present disclosure, in the same first signal line group PZ, the connection lines LJ and the first power supply voltage signal lines PVEE may be formed in different layers.

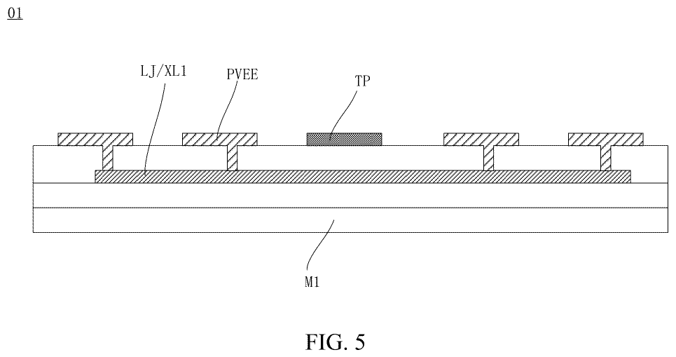

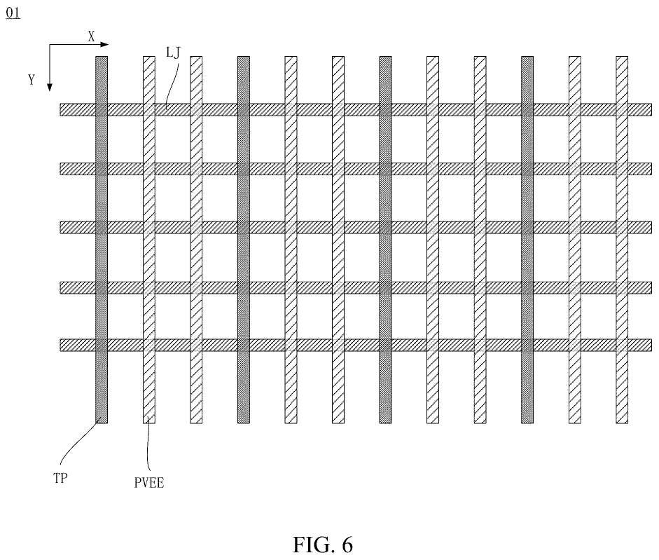

FIG. 5 is a schematic structural diagram of another display panel according to some embodiments of the present disclosure. FIG. 6 is a plan view of another touch signal line and another first power supply voltage signal line according to some embodiments of the present disclosure.

In some embodiments of the present disclosure, as shown in FIG. 5, at least some connection lines LJ and the first power supply voltage signal lines PVEE are formed in different layers. That is, at least some connection lines LJ are formed in a different layer from the touch signal lines TP, and the connection line LJ is electrically connected to the first power supply voltage signal line PVEE through a conductive via hole.

In some embodiments of the present disclosure, as shown in FIG. 5, the layer where the connection line LJ is formed is located on a side of the layer where the first power supply voltage signal line PVEE is formed away from the light exiting surface of the display panel 01. That is, the layer where the connection line LJ is formed is located on a side of the layer where the first power supply voltage signal line PVEE is formed adjacent to the substrate M1.

In some embodiments of the present disclosure, the first power supply voltage signal line PVEE is located between the light-emitting element LG and the transistor array layer M2, and the connection line LJ may be arranged in a film of the transistor array layer M2. In some embodiments of the present disclosure, the connection line LJ is arranged in a film of the transistor array layer M2 where a gate of a transistor is arranged or a film of the transistor array layer M2 where a capacitor electrode is arranged.

In some embodiments of the present disclosure, as shown in FIG. 5 and FIG. 6, the plurality of first power supply voltage signal lines PVEE are all electrically connected by the connection lines LJ. The integral of the plurality of first power supply voltage signal lines PVEE in the first electrode layer 10 is in a mesh shape so as to reduce the voltage drop of the signal transmitted on the first power supply voltage signal lines PVEE.

In this embodiment, the connection line LJ and the touch signal line TP are formed in different layers. In this way, when the plurality of first power supply voltage signal lines PVEE are arranged in a mesh shape, the connection line LJ extending in the first direction X and the touch signal line TP extending in the second direction Y are not connected to each other and insulated from each other, so the first power supply voltage signal lines PVEE are insulated from the touch signal lines TP.

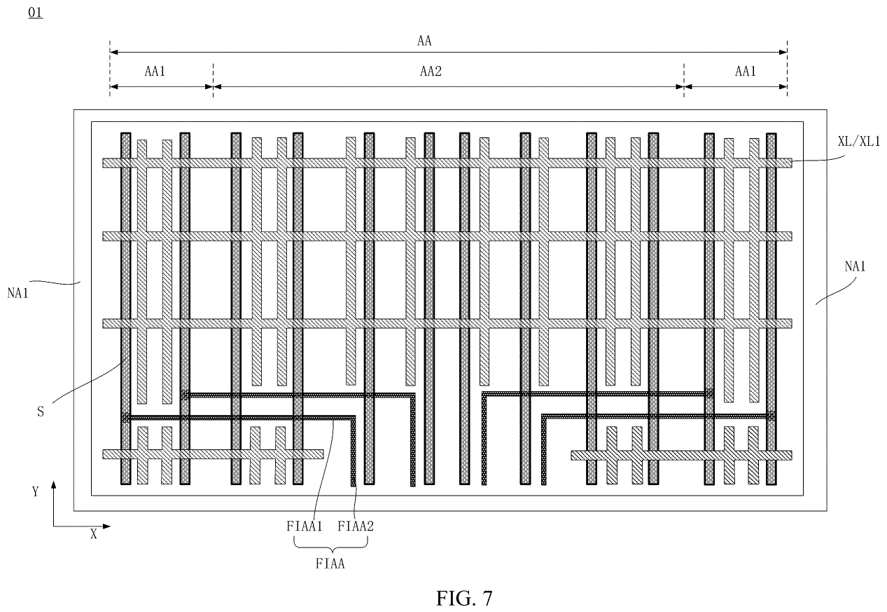

FIG. 7 is a schematic structural diagram of another display panel according to some embodiments of the present disclosure.

In some embodiments of the present disclosure, as shown in FIG. 7, the display panel 01 includes a display region AA and first non-display regions NA1 located on two opposite sides of the display region AA. The first non-display regions NA1 and the display region AA are arranged in the first direction X. The display region AA includes a middle region AA2 and edge regions AA1. The edge region AA1 is closer to the first non-display regions NA1 than the middle region AA2.

The display panel 01 further includes a plurality of data lines S and a plurality of transferring lines FIAA. The data line S extends in the second direction Y, and the plurality of data lines S are arranged in the first direction X. The transferring line FIAA is electrically connected to the data line S in the edge region AA1. The transferring line FIAA extends from the edge region AA1 into the middle region AA2.

At least part of the transferring line FIAA is arranged in a different layer from the data lines S. Therefore, except the data line S electrically connected to the transferring line FIAA, the transferring line FIAA is not electrically connected to other data lines S.

In some embodiments of the present disclosure, as shown in FIG. 7, the same transferring line FIAA includes a first transferring sub-line FIAA1 extending in the first direction X and a second transferring sub-line FIAA2 extending in the second direction Y. The first transferring sub-line FIAA1 is electrically connected to the second transferring sub-line FIAA2.

In some embodiments of the present disclosure, each of the first transferring sub-line FIAA1 and the second transferring sub-line FIAA2 is arranged in a different layer from the data line S. In some embodiments of the present disclosure, the first transferring sub-line FIAA1 is arranged in a different layer from the data line S, and the second transferring sub-line FIAA2 is arranged in a same layer as the data line S.

In some embodiments of the present disclosure, the data line S in the edge region AA1 is connected to the first transferring sub-line FIAA1, and the first transferring sub-line FIAA1 extends into the middle region AA2 of the display region AA and is electrically connected to a driver chip bonded with the display panel 01, realizing the electrical connection between the driver chip and the data line S. In this way, a conventional wire connecting the data line S and the driver chip and inclined to the edge region AA1 is not required, thereby reducing the width of the frame of the display region AA adjacent to the driver chip.

In some embodiments of the present disclosure, as shown in FIG. 7, the display panel 01 further includes dummy wirings XL. The dummy wirings XL are formed in a same layer as the transferring lines FIAA. The dummy wirings XL may be arranged in the region of the display region AA where no transferring line FIAA is arranged. The dummy wirings XL are spaced apart from the transferring lines FIAA. The dummy wirings XL do not transmit an electrical signal.

The dummy wirings XL include a plurality of first wirings XL1 extending in the first direction X. At least some first power supply voltage signal lines PVEE are electrically connected by the first wirings XL1 of the dummy wirings XL. That is, the first wirings XL1 of the dummy wirings XL may serve as the connection lines LJ for connecting the first power supply voltage signal lines PVEE.

In some embodiments of the present disclosure, with the arrangement of the dummy wirings XL, different positions of the display region AA have a consistent line density, so that different positions of the display panel 01 have a consistent parasitic capacitance, thereby achieving display uniformity of the display panel 01.

In addition, since at least some first power supply voltage signal lines PVEE are electrically connected by the first wirings XL1 of the dummy wirings X, at least some first power supply voltage signal lines PVEE may be arranged in a mesh shape. In this way, the voltage drop of the signal transmitted by the first power supply voltage signal line PVEE is reduced, and the accuracy of the signal received by the display electrode 11 is improved.

In some embodiments of the present disclosure, the connection line LJ shown in FIG. 5 is the first wiring XL1 in this embodiment. As shown in FIG. 3 and FIG. 5, the first wiring XL1 is located on a side of the first power supply voltage signal line PVEE away from the first electrode layer 10.

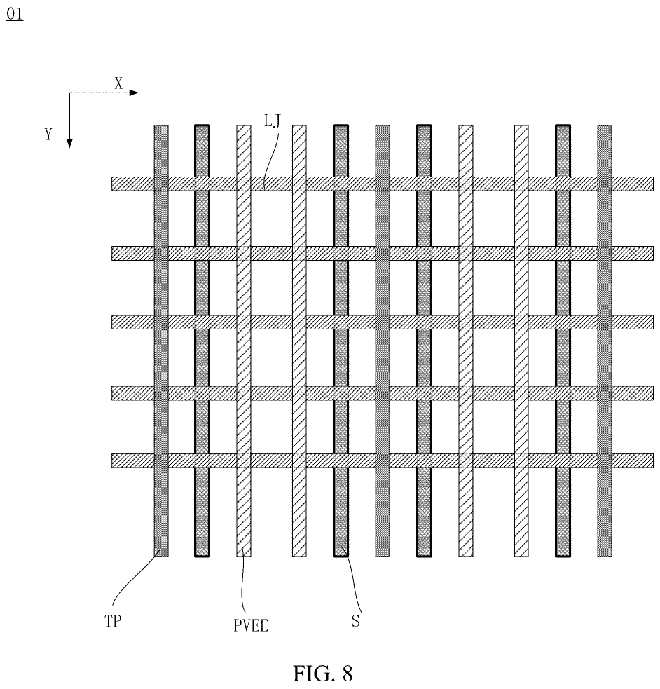

FIG. 8 is a schematic structural diagram of another display panel according to some embodiments of the present disclosure.

In some embodiments of the present disclosure, as shown in FIG. 8, the display panel 01 includes a plurality of data lines S. The data lines S are arranged in the first direction X, and each data line S extends in the second direction Y.

In a thickness direction of the display panel 01, at least part of the touch signal line TP does not overlap with the data line S, and at least part of the first power supply voltage signal line PVEE does not overlap with the data line S.

In this embodiment, at least part of the touch signal line TP does not overlap with the data line S, so that the coupling capacitance between the touch signal line TP and the data line S is reduced, thereby improving the accuracy of the signals transmitted by the touch signal line TP and the data line S. At the same time, at least part of the first power supply voltage signal line PVEE does not overlap with the data line S, so that the coupling capacitance between the first power supply voltage signal line PVEE and the data line S is reduced, thereby improving the accuracy of the signals transmitted by the first power supply voltage signal line PVEE and the data line S.

It should be noted that FIG. 8 only shows an example in which both the touch signal line TP and the first power supply voltage signal line PVEE do not overlap with the data line S. In some embodiments of the present disclosure, for a same touch signal line TP, one part does not overlap with the data line S, and another part overlaps with the data line S. For a same first power supply voltage signal line PVEE, one part does not overlap with the data line S, and another part overlaps with the data line S.

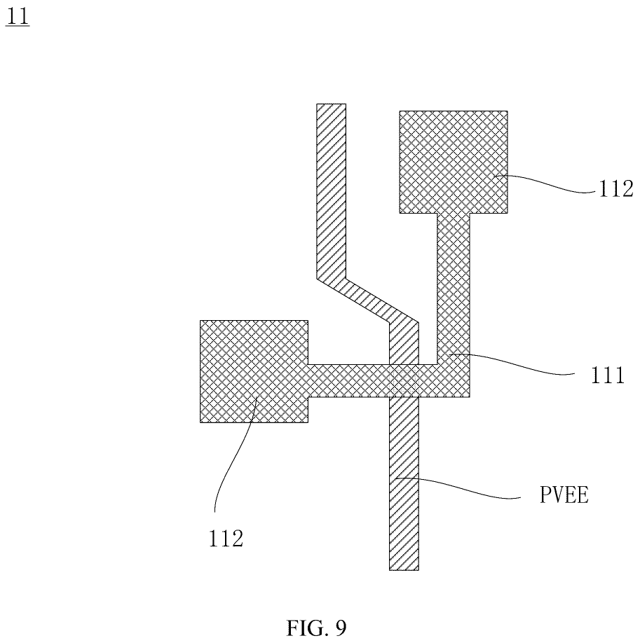

FIG. 9 is a schematic diagram of a display electrode according to some embodiments of the present disclosure.

In some embodiments of the present disclosure, as shown in FIG. 2 and FIG. 3, at least two light-emitting elements LG share a same display electrode 11. That is, along the thickness direction of the display panel 01, one display electrode 11 may cover the light-emitting materials EM of at least two light-emitting elements LG.

In some embodiments of the present disclosure, as shown in FIG. 2 and FIG. 3, the display electrode 11 includes a connection part 111 and a plurality of sub-pixel parts 112. Along the thickness direction H of the display panel 01, the sub-pixel part 112 at least partially overlaps with the light-emitting material EM. In some embodiments of the present disclosure, an area of an orthographic projection of the sub-pixel part 112 on the substrate M1 is greater than an area of an orthographic projection of the light-emitting material EM on the substrate M1. In the same display electrode 11, the plurality of sub-pixel parts 112 are connected by the connection part 111.

In some embodiments of the present disclosure, the sub-pixel part 112 may serve as the cathode of the light-emitting element LG, and the connection part 111 may be electrically connected to the first power supply voltage signal line PVEE through a conductive via hole.

In some embodiments of the present disclosure, as shown in FIG. 2, the sub-pixel part 112 has a circle shape.

In some embodiments of the present disclosure, as shown in FIG. 9, the sub-pixel part 112 has a rectangle shape, and the length and the width of the rectangle may be equal or different.

The sub-pixel part 112 may have other shapes, which is not limited in the present disclosure. In some embodiments of the present disclosure, the shape of the sub-pixel part 112 may be same as that of an aperture of a pixel definition layer. In some embodiments of the present disclosure, the aperture of the pixel definition layer has a rectangle shape, and the sub-pixel part 112 of the display electrode 11 also has a rectangle shape. The sub-pixel part 112 of the display electrode 11 may have a circle shape or other shape, as long as the sub-pixel part 112 can cover the aperture of the pixel definition layer.

In some embodiments of the present disclosure, at least two light-emitting elements LG share one display electrode 11, so that the number of the display electrodes 11 in the display panel 01 is reduced. Since each display electrode 11 is electrically connected to the first power supply voltage signal line PVEE through at least one conductive via hole, by reducing the number of the display electrodes 11 in the display panel 01, the number of the conductive via holes for connecting the display electrodes 11 and the first power supply voltage signal lines PVEE in the display panel 01 is reduced, thereby further reducing the manufacturing difficulty of the display panel 01.

It should be noted that FIG. 2 and FIG. 9 show an example in which two light-emitting elements LG share one display electrode 11, but the number of the light-emitting elements LG sharing the display electrode 11 is not limited.

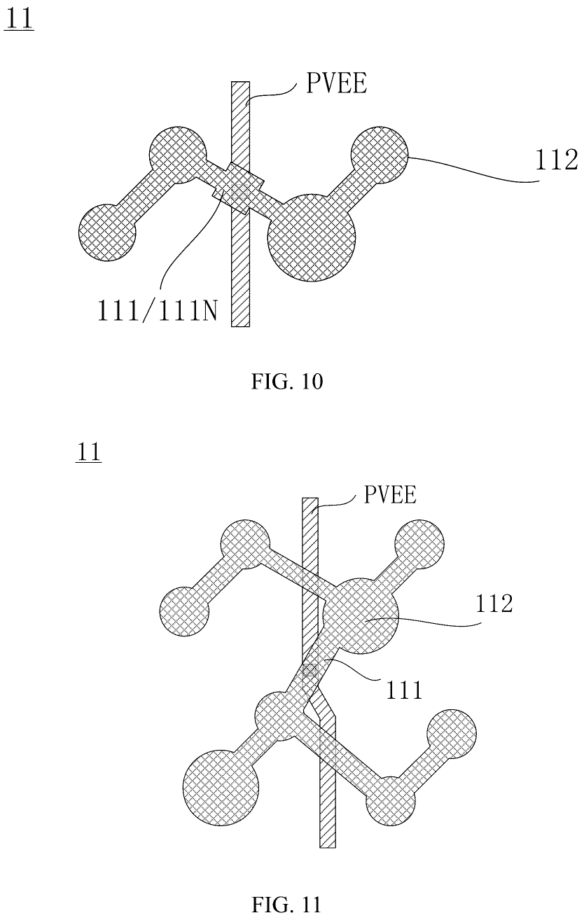

FIG. 10 is a schematic diagram of another display electrode according to some embodiments of the present disclosure. FIG. 11 is a schematic diagram of another display electrode according to some embodiments of the present disclosure.

In some embodiments of the present disclosure, a same one display electrode 11 includes 2ⁿ sub-pixel parts 112, n is greater than or equal to 1. That is, 2ⁿ light-emitting elements LG share a same one display electrode 11.

In some embodiments of the present disclosure, as shown in FIG. 10, a same one display electrode 11 includes 2² sub-pixel parts 112. That is, 4 light-emitting elements LG share one display electrode 11. In some embodiments of the present disclosure, as shown in FIG. 11, a same one display electrode 11 includes 2³ sub-pixel parts 112. That is, 8 light-emitting elements LG share one display electrode 11.

In this manner, as the number of the sub-pixel parts 112 in a same one display electrode 11 is doubled, the number of the conductive via holes for connecting the display electrodes 11 and the first power supply voltage signal lines PVEE in the display panel 01 is reduced by half. As a result, the number of the sub-pixel parts 112 in a same one display electrode 11 can be flexibly arranged according to the design needs.

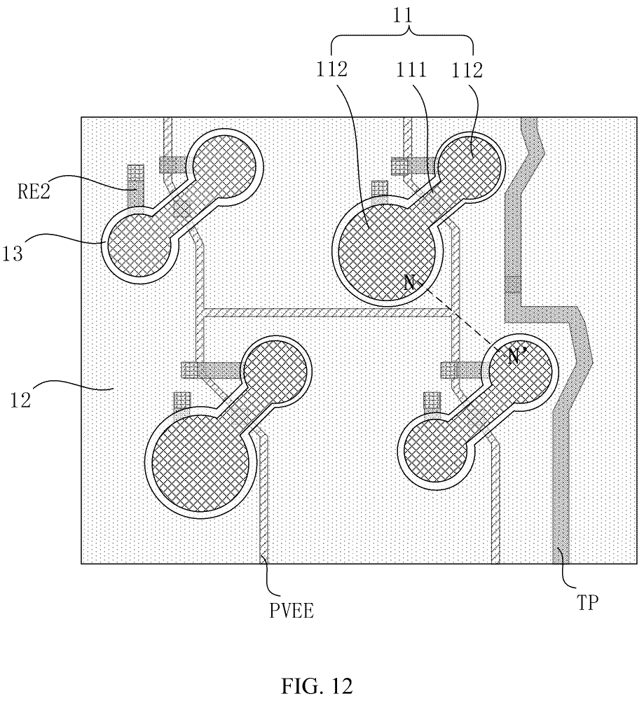

FIG. 12 is another enlarged view of a region Q in FIG. 1 according to some embodiments of the present disclosure.

In some embodiments of the present disclosure, as shown in FIG. 12, the sub-pixel part 112 of the display electrode 11 is adjacent to the touch electrode 12.

In some embodiments of the present disclosure, the connection part 111 of the display electrode 11 is not arranged between the sub-pixel part 112 and the touch electrode 12, and the sub-pixel part 112 and the touch electrode 12 are spaced apart from each other by the blocking wall 13.

In some embodiments of the present disclosure, the touch electrode 12 surrounds the display electrode 11, and the sub-pixel part 112 of the display electrode 11 is adjacent to the touch electrode 12, so that the area of the touch electrode 12 is increased, and the touch sensing performance of the touch electrode 12 is improved without affecting the normal operation of the light-emitting element LG.

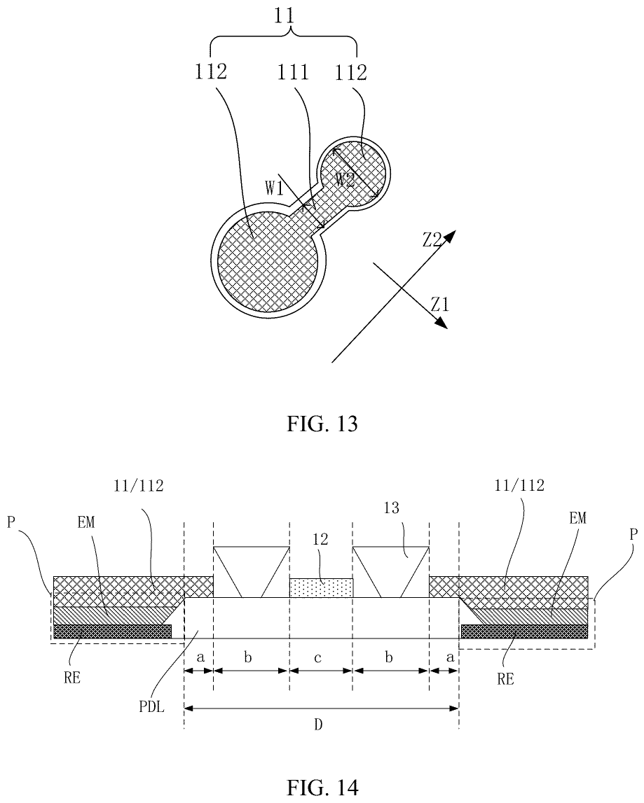

FIG. 13 is an enlarged view of a display electrode in FIG. 12 according to some embodiments of the present disclosure.

As shown in FIG. 12 and FIG. 13, in some embodiments of the present disclosure, in the display electrode 11, a same one connection part 111 is connected to two sub-pixel parts 112 adjacent to the connection part 111, and the connection part 111 is located between the two sub-pixel parts 112 connected to the connection part 111.

A width W1, in a third direction Z1, of the connection part 111 is not greater than a width W2, in the third direction Z1, of the sub-pixel part 112 connected to the connection part 111. The width W1, in the third direction Z1, of the connection part 111 is not greater than the width W2, in the third direction Z1, of any sub-pixel part 112 connected to the connection part 111. It should be noted that the width W2, in the third direction Z1, of the sub-pixel part 112 refers to the maximum width of the sub-pixel part 112 in the third direction Z1. In some embodiments of the present disclosure, the sub-pixel part 112 has a circle shape, and the width W2 of the sub-pixel part 112 in the third direction Z1 is the diameter of the sub-pixel part 112.

The third direction Z1 intersects an extending direction Z2 of the connection part 111. In some embodiments of the present disclosure, the third direction Z1 is perpendicular to the extending direction Z2 of the connection part 111.

In some embodiments of the present disclosure, as shown in FIG. 13, the connection part 111 is a straight line.

When the display electrode 11 includes a plurality of connection parts 111, some connection parts 111 are not connected to the first power supply voltage signal line PVEE through the conductive via hole. The width of these connection parts 111 in the third direction Z1 is greater than or equal to 5 μm. When the connection part 111 is connected to the first power supply voltage signal line PVEE through the conductive via hole, the width of this connection part 111 in the third direction Z1 is less than or equal to the width of the sub-pixel part 112 in the third direction Z1 so as to ensure the accuracy of the conductive via hole for connecting this connection part 111 and the first power supply voltage signal line PVEE.

In some embodiments of the present disclosure, with ensuring the reliability of connections of the sub-pixel parts 112, the width of the connection part 111 is set smaller, so that the overlapping area between the touch electrode 12 and the sub-pixel are increased, and thereby further improving the touch sensing performance of the touch electrode 12.

It should be noted that, in some embodiments of the present disclosure, as shown in FIG. 10, when the connection part 111 is connected to the first power supply voltage signal line PVEE through the conductive via hole, this connection part 111 has a larger width at the position of the conductive via hole and a smaller width at other positions. On the one hand, the overlapping area between the touch electrode 12 and the sub-pixel is large enough, and the touch sensing performance of the touch electrode 12 is improved. On the other hand, a small aperture of the conductive via hole may cause a small contact area at the connection position and cause a large resistance, the larger width at the position of the conductive via hole can avoids that the aperture of the conductive via hole is too small, so that the area of the conductive via hole is increased, the resistance is reduced, thereby improving the stability of the connection between the first power supply voltage signal line PVEE and the display electrode 11.

In some embodiments of the present disclosure, as shown in FIG. 2 and FIG. 3, the display panel 01 further includes a pixel definition layer PDL. The pixel definition layer PDL includes a plurality of apertures P, and the light-emitting materials EM of the light-emitting elements LG are arranged in the plurality of apertures P.

In the thickness direction H of the display panel 01, the touch signal line TP does not overlap with the aperture P, and/or, the first power supply voltage signal line PVEE does not overlap with the aperture P. That is, at least one of the touch signal line TP or the first power supply voltage signal line PVEE does not overlap with the aperture P.

It should be noted that FIG. 2 and FIG. 3 show an example in which both the touch signal line TP and the first power supply voltage signal line PVEE do not overlap with the aperture P.

It should be noted that, in order to ensure the normal operation of the light-emitting element LG, in the thickness direction H of the display panel 01, the sub-pixel part 112 typically covers the aperture P and covers at least part of the driving electrode RE.

In some embodiments of the present disclosure, at least one of the touch signal line TP or the first power supply voltage signal line PVEE does not overlap with the aperture P. Therefore, along the thickness direction H of the display panel 01, at least one of the touch signal line TP or the first power supply voltage signal line PVEE does not overlap with the driving electrode RE covered by the aperture P. The layer of the touch signal line TP and the layer of the first power supply voltage signal line PVEE are typically located on a side of the layer of the driving electrode RE away from the first electrode layer 10, and at least one of the touch signal line TP or the first power supply voltage signal line PVEE does not overlap with the driving electrode RE covered by the aperture P, so that the planarization of this part of the driving electrode RE is ensured, thereby improving the light emission effect of the light-emitting element LG.

FIG. 14 is a cross-sectional view taken along line MN′ in FIG. 12 according to some embodiments of the present disclosure.

In some embodiments of the present disclosure, as shown in FIG. 12, in the display electrode 11, the connection part 111 is electrically connected to two sub-pixel parts 112 adjacent to the connection part 111, and the extending direction of the connection part 111 is same as the arrangement direction of the two sub-pixel parts 112 connected to the connection part 111. That is, the connection part 111 is a straight line, a minimum distance between two adjacent display electrodes 11 is a minimum distance between two adjacent sub-pixel parts 112 thereof.

As shown in FIG. 14, in two adjacent display electrodes 11, the minimum distance between the apertures P of the pixel definition layer PDL covered by the sub-pixel parts 112 is D, a width of the blocking wall 13 is b, a minimum distance between the blocking wall 13 and the aperture P is a, and a distance between two walls 13 is c. The value of the distance c between two walls 13 may limit the width of the touch electrode 12 between two adjacent display electrodes 11. D=2a+2b+c, there are technological limits to the values of a and b.

In the display electrode 11 shown in FIG. 2, the minimum distance between two adjacent display electrodes 11 is the minimum distance D′ between the sub-pixel part 112 of one display electrode 11 and the connection part 111 of the other display electrode 11. Therefore, the minimum distance between two adjacent display electrodes 11 in this embodiment is less than the minimum distance between two adjacent display electrodes 11 shown in FIG. 2.

In some embodiments of the present disclosure, the extending direction of the connection part 111 is same as the arrangement direction of the two sub-pixel parts 112 connected to the connection part 111, so that he minimum distance between two adjacent display electrodes 11 is the minimum distance between two adjacent sub-pixel parts 112 in the two adjacent display electrodes 11. The arrangement of the connection part 11 does not reduce the minimum distance between two adjacent display electrodes 11. Therefore, two adjacent display electrodes 11 have a large distance, ensuring the value of D shown in FIG. 14 is large. Compared with the display electrode 11 shown in FIG. 2, the design space and redundancy rate of the blocking wall 13 between two adjacent display electrodes 11 is increased, and the display electrode 11 and the touch electrode 12 are spaced apart by the blocking wall 13.

In some embodiments of the present disclosure, as shown in FIG. 3, a first conductive via hole K1, a first transferring pad HP1, and a second conductive via hole K2 are provided between the first power supply voltage signal line PVEE and the display electrode 11. The first power supply voltage signal line PVEE is electrically connected to the first transferring pad HP1 through the first conductive via hole K1, and the first transferring pad HP1 is electrically connected to the display electrode 11 through the second conductive via hole K2. That is, the first power supply voltage signal line PVEE is electrically connected to the display electrode 11 through the first conductive via hole K1, the first transferring pad HP1, and the second conductive via hole K2. With the arrangement of the first transferring pad HP1, the depth of the first conductive via hole K1 and the depth of the second conductive via hole K2 are not too large, ensuring the connection reliability between the first power supply voltage signal line PVEE and the display electrode 11.

Along the thickness direction H of the display panel 01, the connection part 111 of the display electrode 11 covers at least part of the second conductive via hole K2.

That is, the connection part 111 of the display electrode 11 is connected to the first power supply voltage signal line PVEE through the second conductive via hole K2, the first transferring pad HP1, and the first conductive via hole K1.

In some embodiments of the present disclosure, along the thickness direction H of the display panel 01, the connection part 111 of the display electrode 11 covers the second conductive via hole K2 and the first transferring pad HP1 so as to ensure the connection reliability between the first power supply voltage signal line PVEE and the display electrode 11.

In some embodiments of the present disclosure, the sub-pixel part 112 covers the light-emitting material EM of the light-emitting element LG, and the connection part 111 of the display electrode 11 is connected to the first power supply voltage signal line PVEE, so that the conductive via hole between the first power supply voltage signal line PVEE and the display electrode 11 does not affect the light-emitting region while ensuring the signal receiving of the display electrode 11, thereby achieving the light-emitting effect of the light-emitting element LG.

In some embodiments of the present disclosure, as shown in FIG. 3, the first transferring pad HP1 and the driving electrode RE are formed in the same layer. That is, the first transferring pad HP1 and the driving electrode RE are simultaneously formed using the same material in the manufacturing process of the display panel 01.

In this embodiment, an additional process for forming the first transferring pad HP1 is not required, thereby simplifying the manufacturing process of the display panel 01 and reducing the cost.

In some embodiments of the present disclosure, as shown in FIG. 3, a same one connection part 111 includes a middle region 111A and edge regions 111B located on two sides of the middle region 111A. The edge region 111B is closer to the sub-pixel part 112 than the middle region 111A.

Along the thickness direction H of the display panel 01, the middle part 111A covers at least part of the second conductive via hole K2. That is, the display electrode 11 is connected to the first power supply voltage signal line PVEE through the middle region 111A of the connection part 111.

In some embodiments of the present disclosure the first power supply voltage signal line PVEE is connected to the middle region 111A of the connection part 111, so that the conductive via hole between the first power supply voltage signal line PVEE and the connection part 111 has a large distance with respect to the light-emitting region, and the light-emitting region is not affected by the position deviation of the second conductive via hole K2.

The middle region 111A of the connection part 111 may have a larger width. On the one hand, the connection reliability between the first power supply voltage signal line PVEE and the connection part 111 is not affected by the position deviation of the second conductive via hole K2. On the other hand, the second conductive via hole K2 has a larger aperture, avoiding a smaller contact area and larger resistance at the connection position due to a smaller aperture.

In some embodiments of the present disclosure, as shown in FIG. 10, the display electrode 11 includes a plurality of connection parts 111. The plurality of connection parts 111 include a first connection part 111N. The number of the sub-pixel parts 112 on a first side of the first connection part 111N is equal to the number of the sub-pixel parts 112 on a second side of the first connection part 111N. The first connection part 111N is located a position close to the center of the display electrode 11.

As shown in FIG. 3, along the thickness direction H of the display panel 01, the first connection part 111N covers at least part of the second conductive via hole K2. That is, the display electrode 11 is connected to the first power supply voltage signal line PVEE through the first connection part 111N.

The first connection part 111N may be connected to the first power supply voltage signal line PVEE through the middle region of the first connection part 111N.

In this embodiment, the display electrode 11 is electrically connected to the first power supply voltage signal line PVEE through the first connection part 111N at the middle position of the display electrode 11. In this way, the voltage signals transmitted from the first power supply voltage signal line PVEE to the sub-pixel parts 112 of the display electrode 11 are substantially the same, thereby achieving the brightness uniformity of the light-emitting elements LG sharing one display electrode 11.

As shown in FIG. 3, in some embodiments of the present disclosure, the display panel 01 further includes a pixel definition layer PDL. The pixel definition layer PDL includes a plurality of apertures P. The light-emitting materials EM of the light-emitting elements LG are arranged in the apertures P.

The driving electrode RE includes a main part RE1 and an extension part RE2 connected to the main part RE1. The extension part RE2 is located on a side of the main part RE1. Along the thickness direction H of the display panel 01, the aperture P overlaps with the main part RE1. The main part RE1 of the driving electrode RE overlaps with the light-emitting material EM of the light-emitting element LG.

In this embodiment, the area of the driving electrode RE is increased due to the arrangement of the extension part RE2, and the extension part RE2 is connected to a signal line in a lower layer through a conductive via hole. In this way, the conductive via hole is not formed at the main part RE1 of the driving electrode RE, so that the main part RE1 of the driving electrode RE is flat, thereby improving the light-emitting effect of the light-emitting element LG.

As shown in the plan views of FIG. 2 and FIG. 12, the extension part RE2 protrudes from the display electrode 11. That is, along the thickness direction H of the display panel 01, at least part of the extension part RE2 is not covered by the display electrode 11.

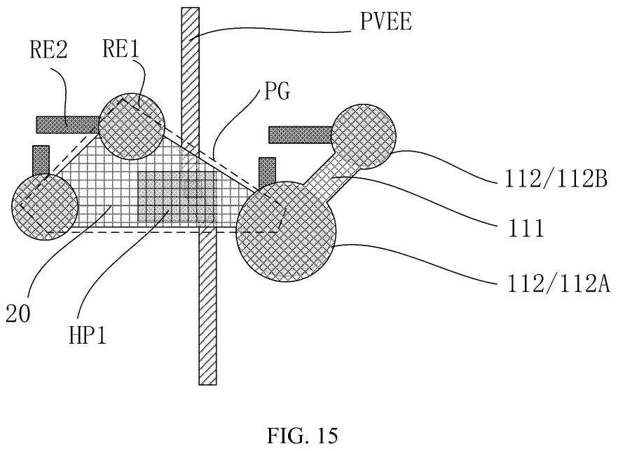

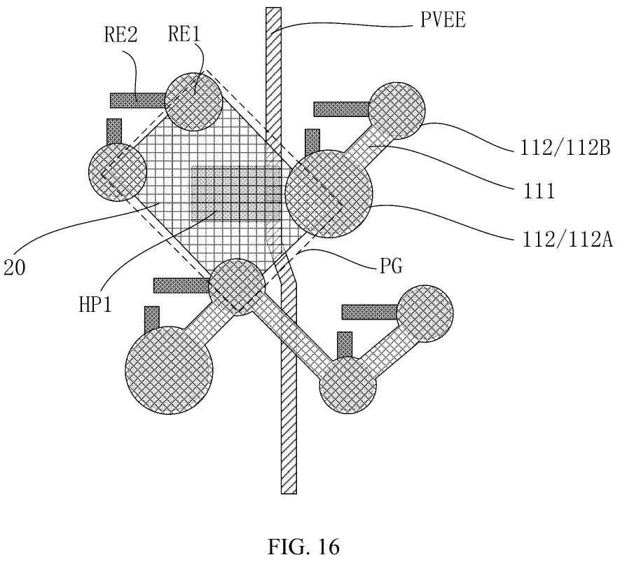

FIG. 15 is a schematic diagram of another display electrode according to some embodiments of the present disclosure. FIG. 16 is a schematic diagram of another display electrode according to some embodiments of the present disclosure.

In some embodiments of the present disclosure, as shown in FIG. 15 and FIG. 16, the display electrode 11 includes at least three sub-pixel parts 112. At least three adjacent sub-pixels parts 112 enclose a polygon region PG. The sub-pixels parts 112 defining the polygon region PG are electrically connected by a same one connection electrode 20, and this connection electrode 20 is located within the polygon region PG. FIG. 15 shows an example in which 3 adjacent sub-pixels parts 112 enclose a polygon region PG. FIG. 16 shows an example in which 4 adjacent sub-pixels parts 112 enclose a polygon region PG.

The connection electrode 20 may be filled within the polygon region PG. That is, the entity part of the display electrode 11 may have a large area within the polygon region PG.

In this embodiment, the sub-pixels parts 112 defining the polygon region PG are electrically connected by the same connection electrode 20, simplifying and reducing the difficulty of the display electrode 11. The entity part of the display electrode 11 within the polygon region PG is electrically connected to the first transferring pad HP1 so as to improve the connection reliability between the first transferring pad HP1 and the display electrode 11. In this way, the area of the first transferring pad HP1 is increased, the resistance at the conductive via hole is reduced, and the voltage drop is reduced.

In some embodiments of the present disclosure, as shown in FIG. 15 and FIG. 16, the sub-pixel parts 112 of the display electrode 11 include first-type sub-pixel parts 112A and second-type sub-pixel parts 112B. The first-type sub-pixel parts 112A enclose and define the polygon region PG. At least some first-type sub-pixel parts 112A and the second-type sub-pixel parts 112B are connected by the connection part 111.

That is, in addition to that the display electrode 11 includes the polygon region PG, the sub-pixel parts 112 enclosing the polygon region PG are also connected to other sub-pixel parts 112 through the straight connection part 111. This increases the structural diversity of display panel 01.

In some embodiments of the present disclosure, as shown in FIG. 15 and FIG. 16, along the thickness direction of the display panel 01, the projection of the polygon region PG covers the first transferring pad HP1, and the polygon region PG does not overlap with the extension part RE2 of the driving electrode RE.

It should be noted that the conductive via hole between the first transferring pad HP1 and the display electrode 11 may be formed by laser. The laser irradiation process may have deviation, and the irradiation range for the conductive via hole may be large.

In this embodiment, in the thickness direction of the display panel 01, the projection of the large-area polygon region PG covers the first transferring pad HP1, so that the first transferring pad HP1 may be designed to have a large area. The first transferring pad HP1 may be connected to the entity part (the connection electrode 20) of the display electrode 11 within the polygon region PG through the conductive via hole. In this way, the connection misplacement between the first transferring pad HP1 and the display electrode 11 due to the process error or variation is solved, the connection reliability between the first transferring pad HP1 and the display electrode 11 is improved, and the reliability of the connection between the first power supply voltage signal line PVEE and the display electrode 11 via the first transferring pad HP1 is improved.

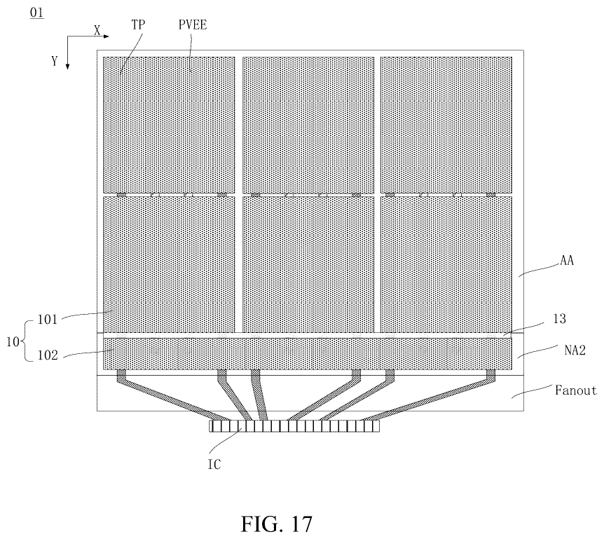

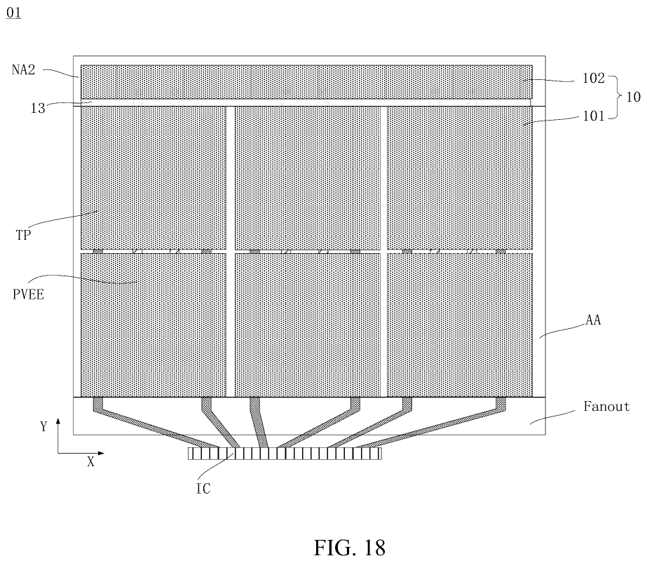

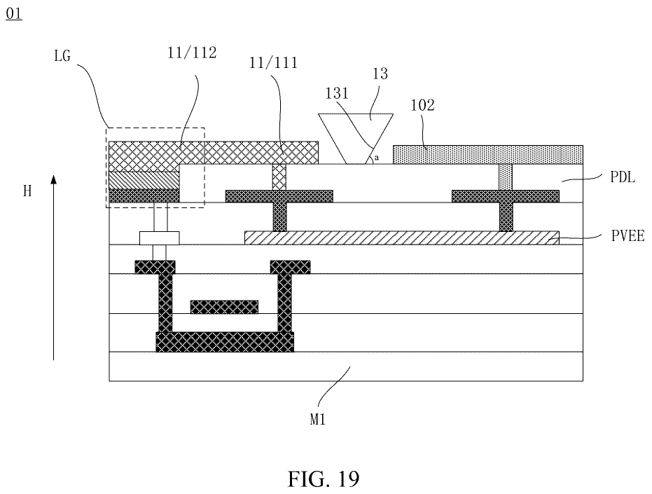

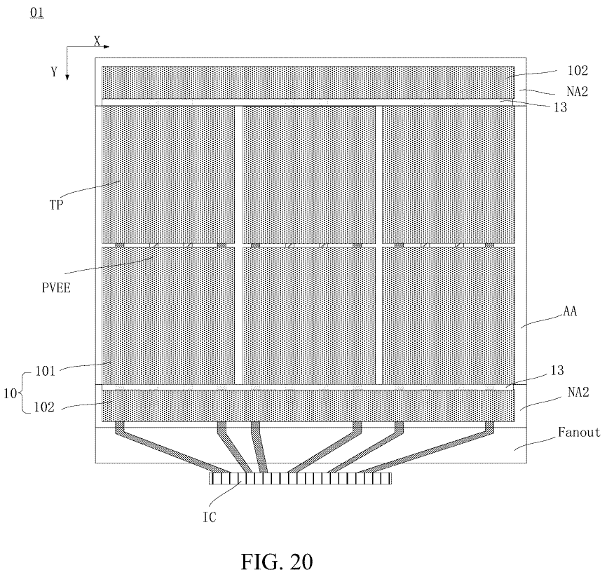

FIG. 17 is a plan view of another display panel according to some embodiments of the present disclosure. FIG. 18 is a plan view of another display panel according to some embodiments of the present disclosure. FIG. 19 is a schematic structural diagram of another display panel according to some embodiments of the present disclosure.

As shown in FIG. 17 and FIG. 18, in some embodiments of the present disclosure, the display panel 01 includes a display region AA and a fan-out region Fanout located on a side of the display region AA. The display region AA and the fan-out region Fanout are arranged along the second direction Y.

The display panel 01 further includes a second non-display region NA2 located on a side of the display region AA. The second non-display region NA2 and the display region AA are arranged along the second direction Y. That is, the second non-display region NA2, the display region AA, and the fan-out region Fanout are arranged along the second direction Y.

In some embodiments of the present disclosure, as shown in FIG. 17, the second non-display region NA2 is located between the display region AA and the fan-out region Fanout.

In some embodiments of the present disclosure, as shown in FIG. 18, the second non-display region NA2 is located on a side of the display region AA away from the fan-out region Fanout.

As shown in FIG. 1, FIG. 2 and FIG. 17, or as shown in FIG. 1, FIG. 2 and FIG. 18, the first electrode layer 10 includes a first part 101 located in the display region AA and a second part 102 located in the second non-display region NA2, and the display electrode 11 and the touch electrode 12 are in the first part 101.

A blocking wall 13 is arranged between the first part 101 and the second part 102, and the first part 101 and the second part 102 are truncated by the blocking wall 13.

When forming the first electrode layer 10, the first part 101 and the second part 102 may be formed by a same evaporation deposition process. The first electrode layer breaks at the blocking wall 13. The part within the display region AA is the first part 101, and the part within the second non-display region NA2 is the second part 102. Since the display region AA also is provided with the blocking wall 13, as shown in FIG. 2, the first part 101 forms the touch electrode 12 and the display electrode 11.

It should be noted that, as shown in FIG. 17 and FIG. 18, there are a plurality of first parts 101 in the display region AA, and the region of one first part 101 may be the region Q in FIG. 1. For ease of description, one first part 101 in FIG. 17 and FIG. 18 is depicted as an integral. However, it should be noted that the first part 101 is divided into the display electrode 11 and the touch electrode 12 separated from each other.

A side of the first power supply voltage signal line PVEE is electrically connected to the second part 102, and the second part 102 is configured to supply a signal to the first power supply voltage signal line PVEE.

That is, the first power supply voltage signal line PVEE is terminated at the second part 102 and does not extend through the fan-out region Fanout for connecting the driver chip IC.

In some embodiments of the present disclosure, as shown in FIG. 19, the first power supply voltage signal line PVEE electrically connected to the display electrode 11 may extend to the second part 102, and is electrically connected to the second part 102 through a conductive via hole. In this way, the signal received from the second part 102 is transmitted to the display electrode 11.

In this case, the touch signal line TP formed in the same layer as the first power supply voltage signal line PVEE may extend through the fan-out region Fanout and then be electrically connected to the driver chip IC. The signal on the second part 102 may be obtained from the driver chip IC via a line formed in a different layer from the touch signal line TP.

In some embodiments of the present disclosure, the driver chip IC may be electrically connected to the second part 102 via a line formed in a layer located on a side of the layer of the touch signal line TP adjacent to the substrate M1. This line may be in a film of the transistor array layer M2. This line passes through the fan-out region Fanout, and then is connected to the second part 102 through a conductive via hole. In this way, the signal transmission path between the second part 102 and the driver chip IC is formed.

The first power supply voltage signal lines PVEE and the touch signal lines TP are formed in the same layer, and the number of the first power supply voltage signal lines PVEE and the number of the touch signal lines TP in the display panel are large. If both the first power supply voltage signal lines PVEE and the touch signal lines TP are electrically connected to the driver chip IC by passing through the fan-out region Fanout, the first power supply voltage signal line PVEE and the touch signal line TP may likely cross and be connected to each other in the fan-out region Fanout, causing short-circuiting between the first power supply voltage signal line PVEE and the touch signal line TP.

In some embodiments of the present disclosure, the second part 102 is used for transmitting signal to the first power supply voltage signal line PVEE, and the first power supply voltage signal line PVEE is terminated at the second part 102 and does not extend into the fan-out region Fanout. In this way, it is avoided that the first power supply voltage signal line PVEE and the touch signal line TP cross and are connected to each other in the fan-out region Fanout, thereby ensuring the stability of the display performance and the touch performance of the display panel 01.

FIG. 20 is a plan view of another display panel according to some embodiments of the present disclosure.

In some embodiments of the present disclosure, as shown in FIG. 20, the display panel 01 may include two second non-display regions NA2. One of the two second non-display regions NA2 is located between the display region AA and the fan-out region Fanout, and the other one of the two second non-display regions NA2 is located on a side of the display region AA away from the fan-out region Fanout.

Similarly, the first electrode layer 10 includes two second parts 102 located in the two second non-display regions NA2 respectively. Both the two second parts 102 may supply the signal to the first power supply voltage signal lines PVEE. Therefore, the uniformity of signals transmitted on different positions of the first power supply voltage signal lines PVEE is improved.

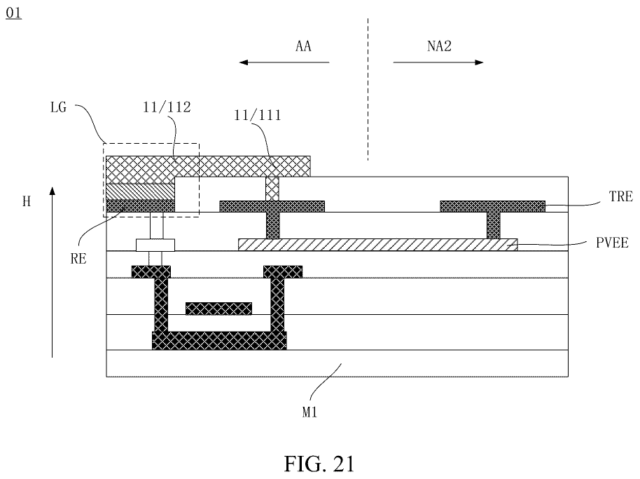

FIG. 21 is a schematic structural diagram of another display panel according to some embodiments of the present disclosure.

In some embodiments of the present disclosure, as shown in FIG. 21, the second non-display region NA2 is provided with a transferring electrode TRE. The transferring electrode TRE and the driving electrode RE of the light-emitting element LG may be arranged in the same layer. The transferring electrode TRE is electrically connected to the first power supply voltage signal lines PVEE. The transferring electrode TRE is configured to supply a signal to the first power supply voltage signal lines PVEE.

That is, the driver chip IC may transmit a signal to the transferring electrode TRE, and thus, the signal transmission to the first power supply voltage signal lines PVEE is achieved through the transferring electrode TRE.

According to the above embodiments, the driver chip IC may transmit the signal to the second part 102 via a line passing through the fan-out region Fanout, and this line is formed in a layer located on a side of the layer where the touch signal line TP is formed adjacent to the substrate M1. This line extends into the second non-display region NA2, and then is connected to the second part 102 of the first electrode layer 10 through a conductive via hole. The conductive via hole may run through the layer where the touch signal line TP is formed. The conductive via hole between the first power supply voltage signal lines PVEE and the second part 102 may also run through the layer where the touch signal line TP is formed.

In this embodiment, the transferring electrode TRE and the driving electrode RE are arranged in the same layer, and the signal is transmitted to the first power supply voltage signal lines PVEE through the transferring electrode TRE. Therefore, the number of the conductive via hole or the depth of the conductive via hole are reduced, thereby simplifying the manufacturing process of the display panel 01.

In some embodiments of the present disclosure, as shown in FIG. 1 and FIG. 2, the blocking wall 13 is arranged between the display electrode 11 and the touch electrode 12, and the display electrode 11 and the touch electrode 12 are separated from each other by the blocking wall 13. Similarly, another wall 13 is arranged between adjacent touch electrodes 12, and adjacent touch electrodes 12 are separated from each other by the blocking wall 13.

As shown in FIG. 17 and FIG. 18, yet another wall 13 is arranged between the first part 101 and the second part 102 of the first electrode layer 10, and the first part 101 and the second part 102 are separated from each other by the blocking wall 13.

In some embodiments of the present disclosure, the blocking walls 13 at the various positions of the display panel 01 may have a same material and same structure, so that these walls 13 can be simultaneously formed, reducing the manufacturing difficulty of the display panel 01. In some embodiments of the present disclosure, the blocking walls 13 at different positions are different in material and structure.

As shown in FIG. 19, the cross-section of the blocking wall 13 taken along the thickness direction of the display panel 01 may be an inverted trapezoid. That is, an angle a formed between a side surface 131 of the blocking wall 13 and the plane of the display panel 01 is an acute angle, and the angle a opens in a direction facing away from the blocking wall 13.

In the manufacturing process of the display panel 01, the blocking wall 13 is formed on the entity part of the pixel definition layer PDL after the pixel definition layer PDL is formed, and the first electrode layer 10 is formed after the blocking wall 13 is formed.

In this way, subsequent to the blocking wall 13, in the process of forming the first electrode layer 10, the first electrode layer 13 breaks at the blocking wall 13.

In some embodiments of the present disclosure, the blocking wall 13 is made of a negative photoresist material. With the properties of the negative photoresist material, the inverted trapezoid-shaped wall 13 is formed by etching. The negative photoresist material includes photosensitive compound and cyclized rubber resin. A portion of the negative photoresist material irradiated by light will be cured and remained, and a portion of the negative photoresist material not irradiated by light will be removed by a developer solution.

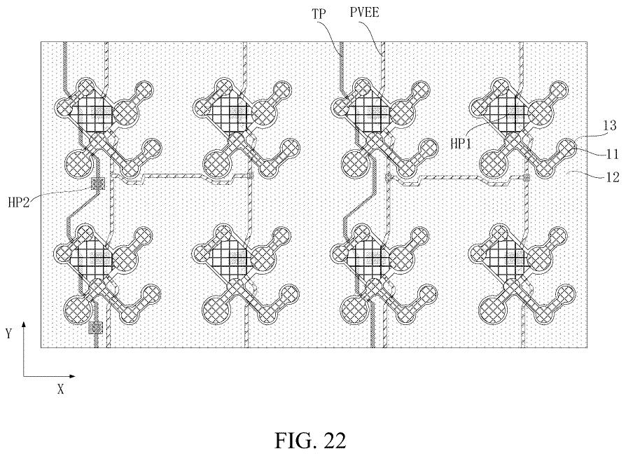

FIG. 22 is another enlarged view of a region Q in FIG. 1 according to some embodiments of the present disclosure.

In some embodiments of the present disclosure, as shown in FIG. 3 and FIG. 22, a second transferring pad HP2 is arranged between the touch signal line TP and the touch electrode 12. The touch signal line TP is electrically connected to the touch electrode 12 through the second transferring pad HP2.

Along the thickness direction H of the display panel 01, the touch electrode 12 covers the second transferring pad HP2.

In some embodiments of the present disclosure, the touch signal line TP is electrically connected to the second transferring pad HP2 through a third conductive via hole K3, and the second transferring pad HP2 is electrically connected to the touch electrode 12 through a fourth conductive via hole K4. In this way, the touch signal line TP and the touch electrode 12 are electrically connected.

In addition, along the thickness direction H of the display panel 01, the second transferring pad HP2 and the touch electrode 12 have a large overlapping area, so as to reduce the affecting of the error in the via formation on the connection reliability between the touch signal line TP and the touch electrode 12.

In some embodiments of the present disclosure, as shown in FIG. 22, the connection position between the second transferring pad HP2 and the touch electrode 12 may be located between two adjacent display electrodes 11 that are arranged in the second direction Y.

In this embodiment, the connection reliability between the touch signal line TP and the touch electrode 12 is not affected due to the too large depth of the conductive via hole between the touch signal line TP and the touch electrode 12.

In some embodiments of the present disclosure, the second transferring pad HP2 and the driving electrode RE of the light-emitting element LG are formed in the same layer. In this way, an additional process of forming the second transferring pad HP2 is not required, thereby reducing the manufacturing difficulty of the display panel 01.

As shown in FIG. 1, FIG. 2, FIG. 12, and FIG. 22, in some embodiments of the present disclosure, a same one touch electrode 12 may surround a plurality of display electrodes 11. That is, a same one region Q may include one touch electrode 12 and a plurality of display electrodes 12, and the touch electrode 12 surrounds the plurality of display electrodes 11. The number of the display electrodes 11 surrounded by one touch electrode 12 is not limited and may be flexibly set according to the touch sensing requirements.

In some embodiments of the present disclosure, one touch electrode 12 surrounds only one display electrode 11. That is, a same one region Q includes one touch electrode 12 and one display electrode 11, and the touch electrode 12 surrounds the display electrode 11.

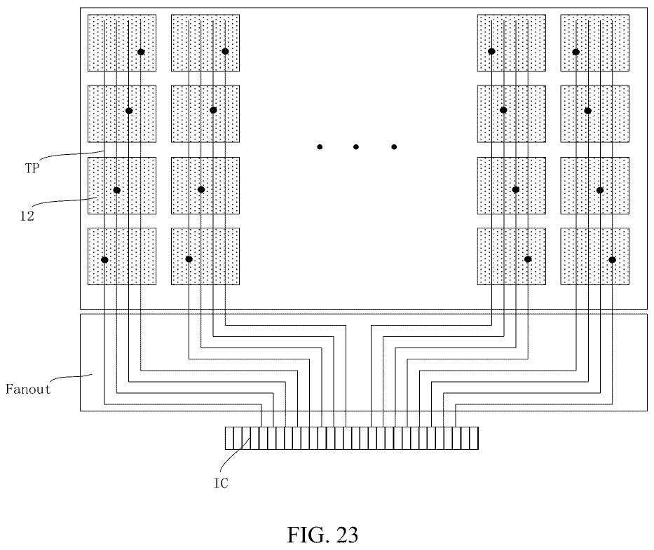

FIG. 23 is a schematic diagram showing connections of touch electrodes according to some embodiments of the present disclosure.

In some embodiments of the present disclosure, the touch electrode 12 is a self-capacitance touch electrode. As shown in FIG. 23, each touch electrode 12 is electrically connected to a corresponding one touch signal line TP, and the touch signal line TP extends through the fan-out region Fanout and then is electrically connected to the driver chip IC.

Each touch electrode 12 is a capacitor, and each touch signal line TP charges the touch electrode 12 electrically connected to the touch signal line TP.

In response to a touch operation, the capacitance of the touch electrode 12 is increased, and the time for charging the touch electrode 12 fully with charges is increased. The driver chip IC determines whether a touch operation exists according to the charging time, and determines the specific coordinates of the touch position according to the changes of the neighboring capacitors. In this way, the touch sensing function of the display panel 01 is realized.

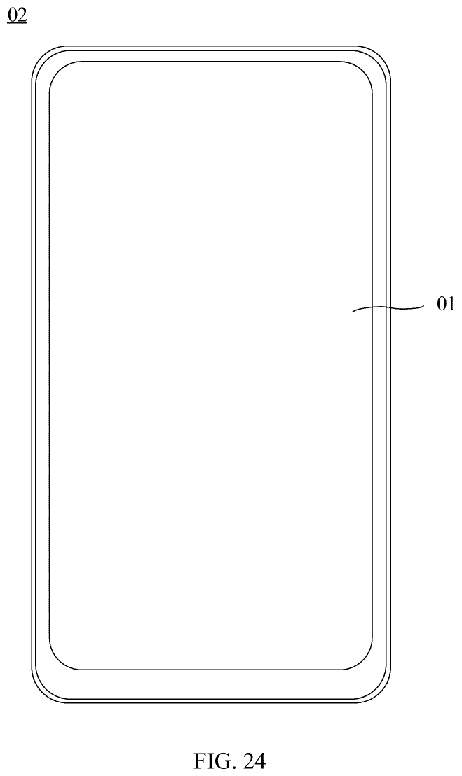

FIG. 24 is a schematic diagram of a display apparatus according to some embodiments of the present disclosure.

Embodiments of the present disclosure further provide a display apparatus 02. As shown in FIG. 24, the display apparatus 02 includes the display panel 01 in the above embodiments. In some embodiments of the present disclosure, the display apparatus 02 may be an electronic device such as a mobile phone, a computer, a television, a vehicle-mounted display device, and the like, which is not limited by the present disclosure.

In the display apparatus 02, the first power supply voltage signal line PVEE and the touch signal line TP are formed in the same layer, so the formation of the first power supply voltage signal line PVEE and the formation of the touch signal line TP may share one mask. In addition, the touch electrode 12 and the display electrode 11 are formed in the same layer, so the formation of the conductive via hole between the first power supply voltage signal line PVEE and the display electrode 11 and the formation of the conductive via hole between the touch signal line TP and the touch electrode 12 may share one mask. In this way, the number of masks required by the manufacturing process of the display panel 01 is reduced, and the manufacturing difficulty and manufacturing cost of the display panel 02 are reduced.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

What is claimed is:

1. A display panel, comprising:
a first electrode layer comprising a plurality of display electrodes and a plurality of touch electrodes, wherein the plurality of display electrodes are arranged in a same layer as the plurality of touch electrodes and insulated from the plurality of touch electrodes;
a plurality of light-emitting elements each comprising a driving electrode, a light-emitting material and a display electrode of the plurality of display electrodes, wherein the driving electrode, the light-emitting material and the display electrode of the plurality of display electrodes are stacked on one another, and the display electrode is located on a side of the light-emitting material facing a light-exiting surface of the display panel;
a plurality of touch signal lines electrically connected to the plurality of touch electrodes; and
a plurality of first power supply voltage signal lines electrically connected to the plurality of display electrodes,
wherein the plurality of first power supply voltage signal lines and the plurality of touch signal lines are formed in a same layer.

2. The display panel according to claim 1, wherein the plurality of touch signal lines is arranged in a first direction and extends in a second direction intersecting the first direction, and the plurality of first power supply voltage signal lines is arranged in the first direction and extends in the second direction,
at least part of the plurality of first power supply voltage signal lines is electrically connected by a plurality of connection lines, and the plurality of connection lines is arranged in the second direction and extends in the first direction.

3. The display panel according to claim 2, wherein the first power supply voltage signal lines comprise first signal line groups, one of the first signal line groups comprises at least two first power supply voltage signal lines adjacent in the first direction, and the first signal line groups are arranged alternately with the plurality of touch signal lines in the first direction.

4. The display panel according to claim 3, wherein the plurality of first power supply voltage signal lines in the same first signal line group are electrically connected by the plurality of connection lines, and the plurality of connection lines and the plurality of first power supply voltage signal lines are formed in a same layer.

5. The display panel according to claim 2, wherein at least part of the plurality of connection lines is formed in a different layer from the plurality of first power supply voltage signal lines.

6. The display panel according to claim 5, wherein the plurality of connection lines is arranged on a side of the plurality of first power supply voltage signal lines away from the first electrode layer.

7. The display panel according to claim 1, wherein at least two light-emitting elements share a same one of the plurality of display electrodes.

8. The display panel according to claim 7, wherein one of the plurality of display electrodes comprises a plurality of connection parts and a plurality of sub-pixel parts, the plurality of sub-pixel parts overlaps the light-emitting material in a thickness direction of the display panel, and the plurality of sub-pixel parts in a same one of the plurality of display electrodes is connected by the plurality of connection parts.

9. The display panel according to claim 8, wherein in the plurality of display electrodes, one of the plurality of connection parts is electrically connected to two sub-pixel parts of the plurality of sub-pixel parts adjacent to the plurality of connection parts, and one of the plurality of connection parts is located between the two sub-pixel parts, and
a width of the plurality of connection parts in a third direction is not greater than a width of the plurality of sub-pixel parts electrically connected to the plurality of connection parts in the third direction, and the third direction intersects an extension direction of the plurality of connection parts.

10. The display panel according to claim 8, wherein in the plurality of display electrodes, the plurality of sub-pixel parts is adjacent to the plurality of touch electrodes.

11. The display panel according to claim 8, further comprising a pixel definition layer comprising a plurality of apertures, and the light-emitting materials of the plurality of light-emitting elements are arranged in the plurality of apertures,
in the thickness direction of the display panel, the plurality of touch signal lines does not overlap with the apertures, and/or, the plurality of first power supply voltage signal lines does not overlap with the plurality of apertures.

12. The display panel according to claim 8, wherein a first conductive via hole, a first transferring pad, and a second conductive via hole are arranged between one of the plurality of first power supply voltage signal lines and one of the plurality of display electrode, the plurality of first power supply voltage signal lines is electrically connected to the first transferring pad through the first conductive via hole, and the first transferring pad is electrically connected to the plurality of display electrodes through the second conductive via hole.

13. The display panel according to claim 12, wherein the plurality of display electrodes comprises a plurality of connection parts, the plurality of connection parts comprises a first connection part having a first end and a second end, and a number of the plurality of sub-pixel parts located on the first end of the first connection part is equal to a number of the plurality of sub-pixel parts located on the second end of the first connection part, and
in the thickness direction of the display panel, the first connection part covers at least part of the second conductive via hole.

14. The display panel according to claim 8, wherein the plurality of display electrodes comprises at least three sub-pixel parts, at least three adjacent ones of the at least three sub-pixel parts define a polygon region, and are electrically connected by a same one of the plurality of connection parts located within the polygon region.

15. The display panel according to claim 14, wherein a projection of the polygon region in the thickness direction of the display panel covers the first transferring pad.

16. The display panel according to claim 2, wherein the display panel has a display region and a fan-out region located on a side of the display region, and the display region and the fan-out region are arranged in the second direction,
the display panel further has a second non-display region, the second non-display region and the display region are arranged in the second direction, the first electrode layer comprises a first part within the display region and a second part within the second non-display region, and the display electrode and the touch electrode are located within the first part, and
a blocking wall structure is provided between the first part and the second part, the first part and the second part are spaced apart by the blocking wall structure, respectively, an end of the first power supply voltage signal line is electrically connected to the second part, and the second part is configured to supply a signal to the plurality of first power supply voltage signal lines.

17. The display panel according to claim 1, wherein a blocking wall structure is provided between the display electrode and the touch electrode, the display electrode and the touch electrode are spaced apart by the blocking wall structure, the blocking wall structure is provided between two adjacent ones of the plurality of touch electrodes that break by the blocking wall structure.

18. The display panel according to claim 16, wherein a cross-section of the blocking wall structure taken along the thickness direction of the display panel is of an inverted trapezoid shape.

19. The display panel according to claim 1, comprising N1 first power supply voltage signal lines and N2 touch signal lines, wherein N1 and N2 are positive integers greater than 1, and ¼≤N2/N1≤½.

20. A display apparatus, comprising: a display panel, wherein the display panel comprises:
a first electrode layer comprising a plurality of display electrodes and a plurality of touch electrodes, wherein the plurality of display electrodes are arranged in a same layer as the plurality of touch electrodes and insulated from the plurality of touch electrodes;
a plurality of light-emitting elements each comprising a driving electrode, a light-emitting material and a display electrode of the plurality of display electrodes, wherein the driving electrode, the light-emitting material and the display electrode are stacked on one another, and the display electrode is located on a side of the light-emitting material facing a light-exiting surface of the display panel;
a plurality of touch signal lines electrically connected to the plurality of touch electrodes; and
a plurality of first power supply voltage signal lines electrically connected to the plurality of display electrodes,
wherein the plurality of first power supply voltage signal lines and the plurality of touch signal lines are formed in a same layer.
